(19) United States
(12) Patent Application Publication
(10) Pub. No.: US 2002/0192906 A1
(43) Pub. Date: Dec. 19, 2002

(54) Method for forming a capacitor of a semiconductor device

(75) Inventors: Kwang-seok Jeon, Icheon (KR); Sang-ho Woo, Icheon (KR); Eui-sik Kim, Seoul (KR)

Correspondence Address: MARSHALL, GERSTEIN & BORUN, 6300 SEARS TOWER, 233 SOUTH WACKER, CHICAGO, IL, 60606-6357, US

(73) Assignee: Hynix Semiconductor Inc., Kyoungki-do (KR)

(21) Appl. No.: 10/147,752

(22) Filed: May 16, 2002

(30) Foreign Application Priority Data
May 16, 2001 (KR) 2001-26848

(51) Int. Cl. H01L 21/8242; H01L 21/20

(52) U.S. Cl. 438/255; 438/398

(57) ABSTRACT

Disclosed is a method for forming a capacitor of a semiconductor device. When the lower electrodes of the capacitor are formed, the growth of hemispherical grains is suppressed at the uppermost part and the outer part of the lower electrodes, so as to prevent the generation of a bridge between the lower electrodes of the capacitor thereby increasing product yield, capacitance and reliability.

### BACKGROUND

1. Technical Field

A method for forming a capacitor of a semiconductor device is disclosed, and more particularly, to a method for forming a capacitor of a semiconductor device is disclosed, which can prevent the generation of an undesirable bridge between the lower electrodes of the capacitor by suppressing growth of a hemispherical grain on an uppermost part and an outer part of the lower electrodes.

2. Description of the Related Art

As the degree of integration of a semiconductor device increases, the area in which a capacitor can be formed decreases. In order to form a capacitor with a high capacitance on such a small area, many methods have been proposed such as a method which forms a thin dielectric film, a method is employed which utilizes a substance of high permittivity as a dielectric film, or a method is employed which increases an effective area of the electrodes by forming the electrodes with a three-dimensional construction such as a cylinder shape or a fin shape or by a polycrystalline silicon growth method that grows a hemispherical grain (HSG) on the surface of the lower electrodes.

The basic construction of the capacitor and the method for forming the capacitor according to the last method discussed above increases the effective area of the electrodes by growing the HSG on the surface of the lower electrodes and is disclosed in the U.S. Pat. No. 5,597,756. According to the polycrystalline silicon growth method that grows the HSG on the lower electrodes, in order to grow the HSG, lower electrodes made of amorphous silicon are formed, silane gas is injected as a seed gas, and then silicon atoms are migrated around the seed gas in a vacuum status to grow the HSG. Alternatively, a method is employed that migrates silicon atoms on the surface at a proper temperature and pressure according to an In-Situ method consecutively without a seeding process while depositing the amorphous silicon doped with impurities. In that case, the migration velocity and amount of the silicon atoms depend on the injection time, flow rate or the temperature of the seed gas, or the migration time, temperature and the pressure of the silicon atoms, as well as the doping density of the impurities, which determine the growing size and amount of the HSG.

FIGS. 1 to 4 are cross sectional views illustrating successively the conventional method for forming a capacitor of a semiconductor device.

As shown in FIG. 1, a lower layer having an insulation film, gates and bit lines is formed on a semiconductor substrate, a first layer-insulation film 10 is formed by deposition, a contact plug 20 connected to a lower electrode of a capacitor is formed, and then the contact plug 20 is planarized.

Then, an amorphous silicon film 40 containing impurities and a second layer-insulation film 30 are formed by deposition on the surface where the contact plug 20 has been planarized. The second layer-insulation film 30 is formed by one of Phospho Silicate Glass (PSG), Boro Phospho Silicate Glass (BPSG), Tetra-Ethyl Ortho Silicate (TEOS), and High Density Plasma (HDP). The patterning is then performed to form lower electrodes by etching with a mask 35 until the first layer-insulation film 10 is exposed.

Subsequently, on the upper surface of the patterning for forming the electrodes, an amorphous silicon layer 40′ is formed by deposition to a thickness ranging from 100 to 2000 Å as shown in FIG. 2. At that time, the amorphous silicon film 40′ is deposited by using one of SiH₄, Si₂H₆, SiH₃Cl₂ and PH₃ gases at a temperature ranging from 450 to 560° C. and pressure ranging from 0.1 to 300 torr so as to apply a polycrystalline silicon growth technology.

As shown in FIG. 3, the shape of the lower electrodes is formed by isolating the cells from each other as the amorphous silicon film 40′ deposited on the upper surface of the result is etched back, and the cylindrical lower electrodes 60 are formed by eliminating the second layer-insulation film 30.

The lower electrodes 60 are formed by forming hemispherical grains (HSG) on the amorphous silicon film 40′ with the polycrystalline silicon growth technology after forming the cylindrical lower electrodes 60 as described above.

However, there is a problem that unwanted residual material may exist or adhere to the structure again while isolating the cells by etching back the amorphous silicon film 40′, which may form a bridge between cells during a following thermal process or the growth of the polycrystalline silicon.

Furthermore, the spatial margin between the cells may be deteriorated by the thickness of the hemispheric grains grown on the outer part of the lower electrodes 60. And in particular, the lower electrode cylinder may break when the height of the lower electrode is increased to increase the charging capacity of the cell capacitor.

### SUMMARY OF THE DISCLOSURE

To solve the above problems, a method for forming a capacitor of a semiconductor device is disclosed where a bridge is not formed between the lower electrodes of the capacitor by suppressing the growth of the hemispherical grain growing on the uppermost part and the outer part of the lower electrodes, while the lower electrodes of the hemispherical grain capacitor are formed.

Further, a method for forming a capacitor of a semiconductor device disclosed comprising the steps of: forming a contact plug on a first layer-insulation film stacked on gate electrodes and bit lines formed on a semiconductor substrate; forming a lower electrode contact hole by patterning, after forming a second layer-insulation film on a surface formed with the contact plug; forming an amorphous silicon film on a surface formed with the lower electrode contact hole, depositing a flattening film, and isolating cells from each other; performing a post-etch treatment after isolating the cells; eliminating residual material on the lower electrodes after performing the post-etch treatment; growing hemispherical grains after eliminating the residual material; and forming a dielectric film and an upper electrode on the lower electrodes on which the hemispherical grains have grown.

The post-etch treatment is performed with gases selected from the group consisting of C₂F₆, CHF₃, CH₃, SF₆, CF₄ and mixtures thereof. This treatment can also be performed with a mixture of at least one of C₂F₆, CHF₃, CH₃, SF₆ and CF₄ gases and at least one of Ar, O₂, Cl₂ and HF gases.

The growth of the hemispherical grains is suppressed since the post-etch treatment is performed after the lower electrodes are formed, and no bridge is generated by the isolation between the lower electrodes since the hemispherical grains are not formed on the outer part of the lower electrodes due to the second layer-insulation film remaining between the lower electrodes.

### BRIEF DESCRIPTION OF THE DRAWINGS

Other objects and aspects of the disclosure will become apparent from the following description of embodiments with reference to the accompanying drawings, wherein:

FIGS. 1 to 4 are cross sectional views illustrating successively a conventional method for forming a capacitor of a semiconductor device;

FIGS. 5 to 9 are cross sectional views illustrating successively a disclosed method for forming a capacitor of a semiconductor device;

FIGS. 10a to 10e are SEM pictures illustrating a hemispherical grain grown after a post-etch treatment with an etching gas for suppressing growth of the hemispherical grain; and

FIG. 11 is a SEM picture of lower electrodes formed by a disclosed method for forming a capacitor of a semiconductor device.

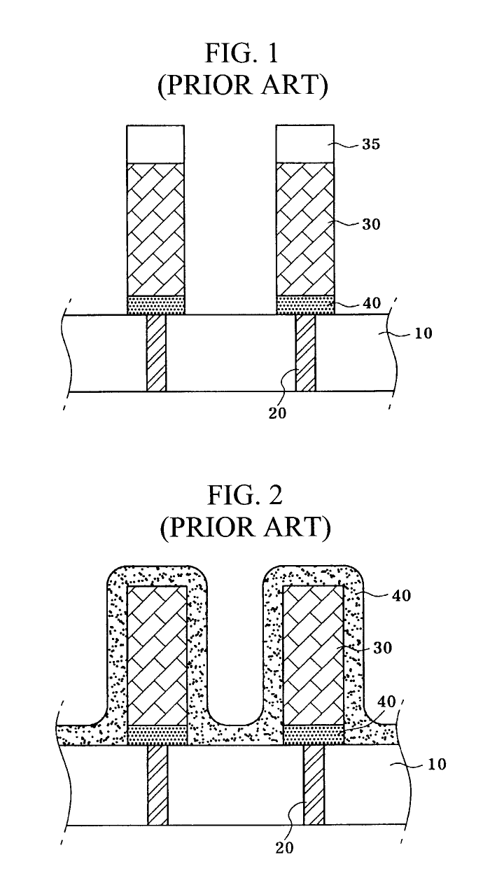

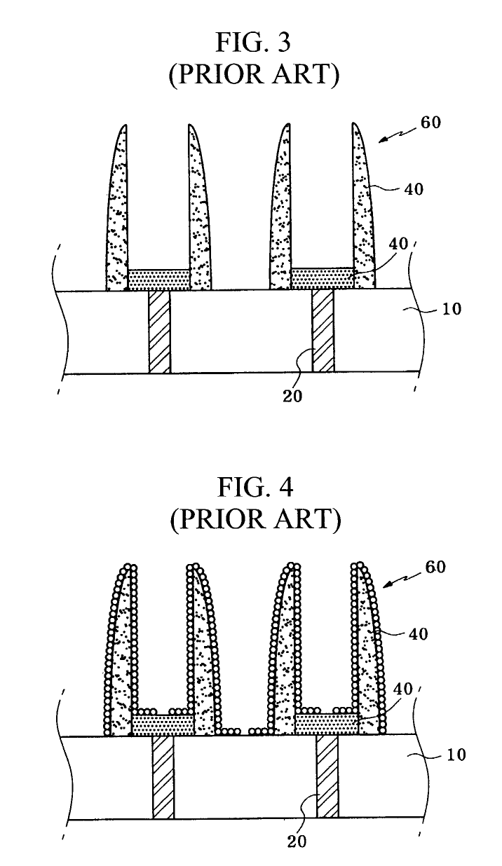

### DETAILED DESCRIPTION OF THE PRESENTLY PREFERRED EMBODIMENTS

The disclosed methods and resulting capacitors will hereinafter be described in more detail by a preferred embodiment. The disclosed methods are only examples and do not limit the scope of this disclosure. Parts with the same components in the conventional art are referred to with the same reference numerals and names.

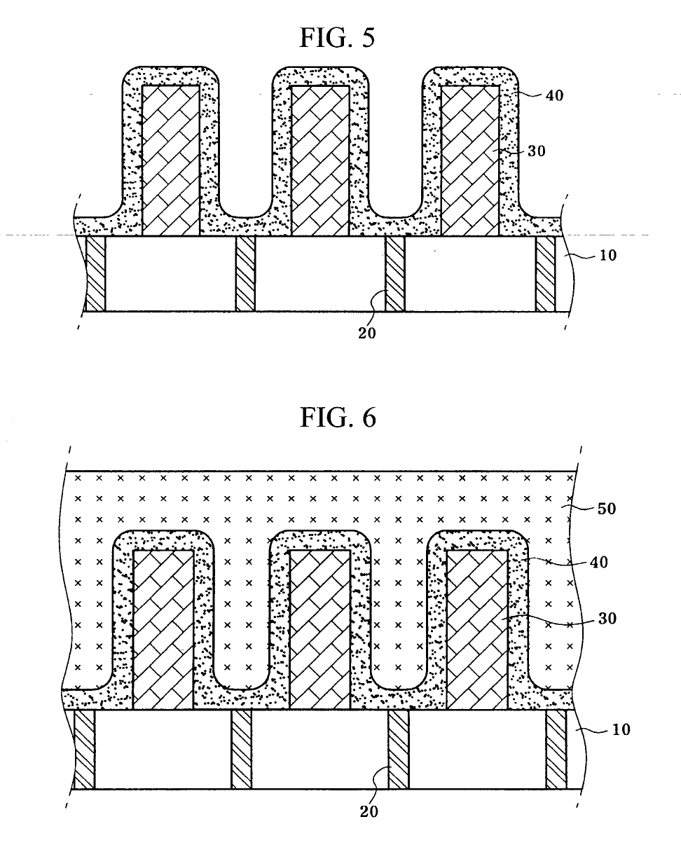

FIGS. 5 to 9 are cross sectional views illustrating successively a disclosed method for forming a capacitor of a semiconductor device according to the present invention.

As shown in FIG. 5, gate electrodes and bit lines are formed on the substrate of a semiconductor device, a first layer-insulation film 10 is stacked on the gate electrodes and bit lines, and then contact plugs 20 are formed on the first layer-insulation film 10.

Then, lower electrode contact holes are formed by patterning after a second layer-insulation film 30 is formed on the surface formed with the contact plugs 20.

The second layer-insulation film 30 may be formed by one of Phospho Silicate Glass (PSG), Boro Phospho Silicate Glass (BPSG), Tetra-Ethyl Ortho Silicate (TEOS), High Density Plasma (HDP), High Thermal Oxide (HTO), and Medium Thermal Oxide (MTO).

An amorphous silicon film 40 is then deposited on the surface formed with the lower electrode contact holes. The amorphous silicon film 40 can be a single layer film or a double layer film.

The amorphous silicon film 40 is deposited to a thickness ranging from about 100 to about 2000 Å, by using one of SiH₄, Si₂H₆, SiH₃Cl₂ and PH₃ gases at a temperature ranging from about 450 to about 560° C. and pressure ranging from about 0.1 to about 300 torr, so that polycrystalline growth technology can be utilized.

As shown in FIG. 6, a flattening or planar film 50 is then formed on the upper surface of the amorphous silicon film 40 by using Photo Resist (PR), Spin On Glass (SOG), Hemispherical Silicon Grain (HSG), Phospho Silicate Glass (PSG), or Boro Phospho Silicate Glass (BPSG), which planarizes the result.

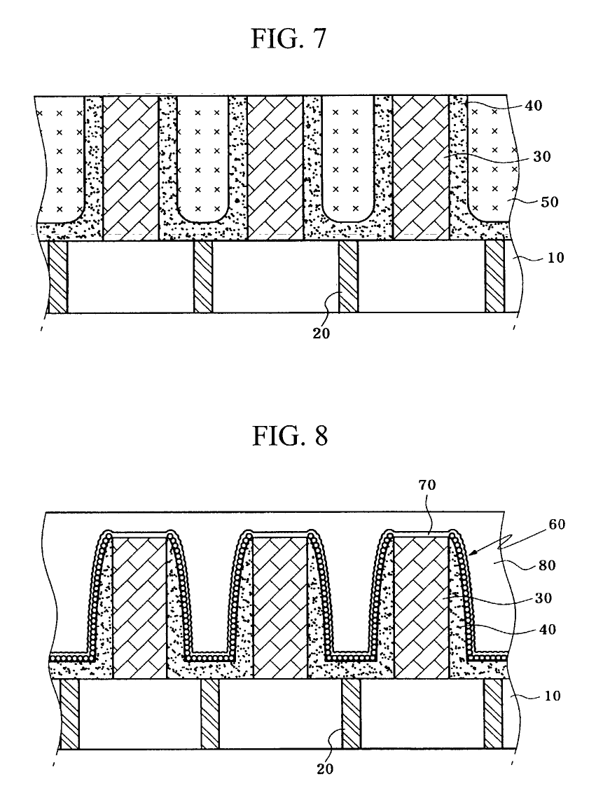

Then, as shown in FIG. 7, the cells are isolated from each other by etching back the films 50 and 40 to expose the second layer-insulation film 30. Further, the cells can also be isolated from each other not by etching back as described above but by a CMP process to expose the second layer-insulation film 30.

After the cells are isolated from each other by the exposure of the second layer-insulation film 30, a post-etch treatment is performed to eliminate the remaining portions flattening film 50 in the lower electrodes 60 as shown in FIG. 8.

The post-etch treatment is performed with at least one of C₂F₆, CHF₃, CH₃, SF₆ and CF₄ gases, or with a mixture of at least one of C₂F₆, CHF₃, CH₃, SF₆ and CF₄ gases and at least one of Ar, O₂, Cl₂ and HF.

Since the uppermost part of the lower electrodes 60 are exposed to the etching gas by the post-etch treatment, while the hemispherical grains are growing in the following process, the growth of the hemispherical grains can be suppressed selectively.

The growth of the grains can be suppressed by a degree of as much as 50% when using SF₆ in comparison with the mixture of Cl₂ and O₂, and the gases can be used selectively.

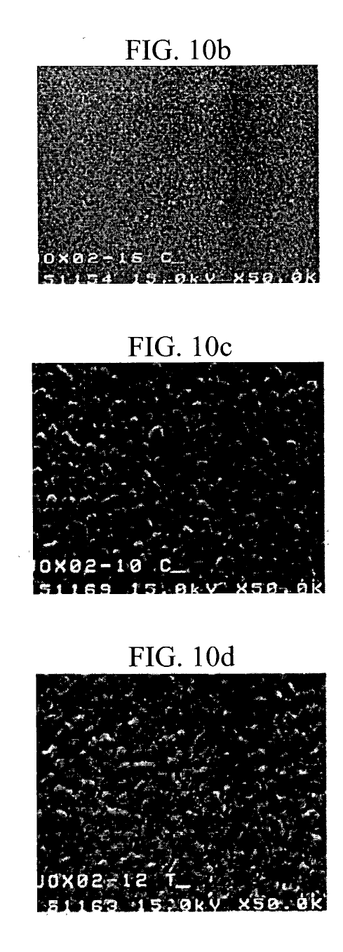

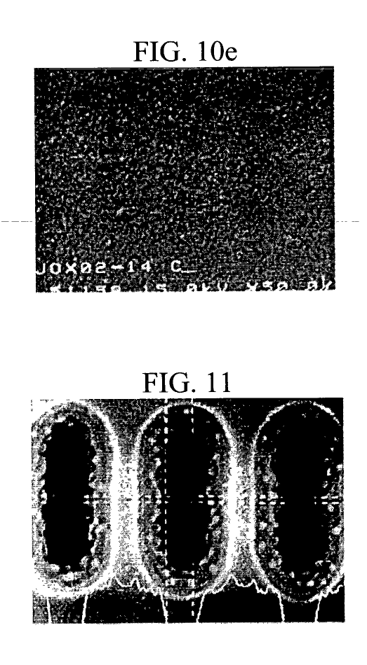

FIGS. 10a to 10e are SEM pictures showing a hemispherical grain grown after the post-etch treatment with etching gas for suppressing the growth of the hemispherical grain. In the drawings, FIG. 10a is a SEM picture when the hemispherical grains are grown after etching with the C₆F₆ gas, FIG. 10b is an SEM picture when the hemispherical grains are grown after etching with the mixture of CHF₃ and CF₄ gases, FIG. 10c is an SEM picture when the hemispherical grains are grown after etching with the SF₆ gas, FIG. 10d is an SEM picture when the hemispherical grains are grown after etching with the mixture of Cl₂ and O₂gases, and FIG. 10e is a SEM picture when the hemispherical grains are grown after etching with the mixture of CH₃ and Ar gases.

As the etching gas capable of suppressing the growth of the hemispherical grains is used in the post-etch treatment, the growth of the hemispherical grains is suppressed where it is exposed to the etching gas, as shown in FIGS. 10a to 10e.

After that, in order to eliminate the flattening film 50 remaining on the lower electrodes 60, a cleaning process is performed by a wet etching or a dry etching.

As described above, the hemispherical grains are grown after the flattening film 50 in the lower electrodes 60 has been eliminated. Therefore, the lower electrodes 60 of the capacitor are formed while the hemispherical grains are formed only at the inside of the lower electrodes 60, the growth of the hemispherical grains is suppressed at the uppermost part exposed to the gas in the post-etch treatment process, and the second layer-insulation film 30 remains at the outer area of the lower electrodes 60 to suppress the growth of the hemispherical grains.

The capacitor is then completed by forming a dielectric film 70 and upper electrodes 80 on the upper surface of the lower electrodes 60.

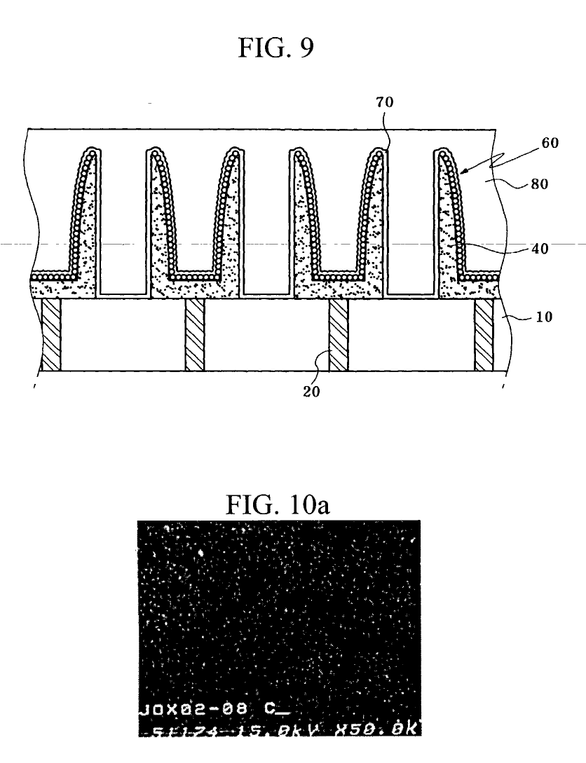

If the dielectric film 70 is formed only at the inside of the lower electrodes 60 while the second layer-insulation film 30 remains between the cells, the charging capacitance may be insufficient. Therefore, the charging capacitance can be increased by forming the capacitor by depositing the dielectric film 70 and upper electrodes 86 after isolating the cells from each other by etching the second layer-insulation film 30, as shown in FIG. 9.

FIG. 11 is an SEM picture of lower electrodes formed by the disclosed method for forming a capacitor of a semiconductor device, wherein the hemispherical grains are grown on the uppermost part of the lower electrodes 60 by using the etching gas capable of suppressing the growth of the hemispherical grains in the post-etch treatment.

As shown in the figure, the hemispherical grains are grown only at the inside of the lower electrodes.

As described above, when forming lower electrodes of hemispherical grain capacitor, the growth of the hemispherical grains growing at the uppermost part and the outer part of the lower electrodes is suppressed so as not to form a bridge between the lower electrodes of the capacitor, which may improve the yield of the semiconductor.

Furthermore, since the growth of the hemispherical grains is suppressed only at the local area of the uppermost part of the lower electrodes, the generation of the bridge between the cells is prevented without the deterioration of the entire capacitance, therefore improving the electrical properties.

Although preferred embodiments have been described, it will be understood by those skilled in the art that this disclosure should not be limited to the described preferred embodiment, but various changes and modifications can be made within′ the spirit and the scope of this disclosure. Accordingly, the scope of this disclosure is not limited to the described ranges but the following claims.

What is claimed is:

1. A method for forming a capacitor of a semiconductor device, the method comprising:
forming contact plugs in a first layer-insulation film stacked on gate electrodes and bit lines formed on a semiconductor substrate;
forming a second layer-insulation film on a surface formed by the contact plug and first layer-insulation film and forming lower electrode contact holes by patterning the second layer-insulation film,
forming an amorphous silicon film on a surface comprising the lower electrode contact holes and patterned second-insulation film, depositing a flattening film, and isolating resulting cells from each other by removing upper portions of the flattening film and amorphous silicon film;
performing a post-etch treatment after isolating the cells to produce lower electrodes;
eliminating residual material on the lower electrode after performing the post-etch treatment;
growing hemispherical grains on the lower electrodes after eliminating the residual material; and
forming a dielectric film and an upper electrode on the lower electrodes on which the hemispherical grains have grown.

2. The method of claim 1, wherein the second layer-insulation film is formed with one of PSG, BPSG, TEOS, HDP, HTO and MTO.

3. The method of claim 1, wherein the amorphous silicon film is deposited to a thickness ranging from about 100 to about 2000 Å, using gases selected from the group consisting of SiH₄, Si₂H₆, SiH₃Cl₂, PH₃, and mixtures thereof and at a temperature ranging from about 450 to about 560° C. and a pressure ranging from about 0.1 to about 300 torr.

4. The method of claim 1, wherein the amorphous silicon film is formed as a single film or a double film.

5. The method of claim 1, wherein the flattening film is formed by at least one of PR, SOG, HSG, PSG and BPSG.

6. The method of claim 1, wherein the isolating of the cells is performed by exposing the second layer-insulation film with a CMP process.

7. The method of claim 1, wherein the isolating of the cells is performed by exposing the second layer-insulation film with an etch back process.

8. The method of claim 1, wherein the post-etch treatment is performed with gases selected from the group consisting of C₂F₆, CHF₃, CH₃, SF₆, CF₄ and mixtures thereof.

9. The method of claim 1, wherein the post-etch treatment is performed with a mixture of at least one of C₂F₆, CHF₃, CH₃, SF₆ and CF₄ gases and at least one of Ar, O₂, Cl₂ and HF gases.

10. The method of to claim 1, wherein the residual material on the lower electrodes is cleaned by dry etching or wet etching.

11. A method for forming a capacitor of a semiconductor device, comprising the steps of:
forming contact plugs in a first layer-insulation film stacked on gate electrodes and bit lines formed on a semiconductor substrate;
forming a second layer-insulation film on a surface formed by the contact plug and first layer-insulation film and forming lower electrode contact holes by patterning the second layer-insulation film,
forming an amorphous silicon film on a surface comprising the lower electrode contact holes and patterned second-insulation film, depositing a flattening film, and isolating resulting cells from each other by removing upper portions of the flattening film and amorphous silicon film;
performing a post-etch treatment after isolating the cells to produce lower electrodes;
eliminating residual material on the lower electrode after performing the post-etch treatment;
growing hemispherical grains on the lower electrodes after eliminating the residual material;
eliminating the second layer-insulation film formed between the lower electrodes; and
forming a dielectric film and an upper electrode on the lower electrodes on which the hemispherical grains have grown.

12. The method of claim 11, wherein the second layer-insulation film is formed with one of PSG, BPSG, TEOS, HDP, HTO and MTO.

13. The method of claim 11, wherein the amorphous silicon film is deposited to a thickness ranging from about 100 to about 2000 Å, using gases selected from the group consisting of SiH₄, Si₂H₆, SiH₃Cl₂, PH₃, and mixtures thereof and at a temperature ranging from about 450 to about 560° C. and a pressure ranging from about 0.1 to about 300 torr.

14. The method of claim 11, wherein the amorphous silicon film is formed as a single film or a double film.

15. The method of claim 11, wherein the flattening film is formed by at least one of PR, SOG, HSG, PSG and BPSG.

16. The method of claim 11, wherein the isolating of the cells is performed by exposing the second layer-insulation film with a CMP process.

17. The method of claim 11, wherein the isolating of the cells is performed by exposing the second layer-insulation film with an etch back process.

18. The method of claim 11, wherein the post-etch treatment is performed with gases selected from the group consisting of C₂F₆, CHF₃, CH₃, SF₆, CF₄ and mixtures thereof.

19. The method of claim 11, wherein the post-etch treatment is performed with a mixture of at least one of C₂F₆, CHF₃, CH₃, SF₆ and CF₄ gases and at least one of Ar, O₂, Cl₂ and HF gases.

20. The method of to claim 11, wherein the residual material on the lower electrodes is cleaned by dry etching or wet etching.
